(19) United States
(12) Patent Application Publication
(10) Pub. No.: US 2026/0347232 A1
(43) Pub. Date: Nov. 5, 2026

(54) HYBRID LASER PROCESSING APPARATUS AND METHODS

(71) Applicant: QMC Co., Ltd., Anyang-si (KR)

(72) Inventor: Bengso Ryu, Incheon (KR)

(21) Appl. No.: 19/193,968

(22) Filed: Apr. 30, 2025

(51) Int. Cl. C03B 33/02; C03C 15/00; H10W 70/05

(52) U.S. Cl. CPC C03B 33/0222; C03C 15/00; H10W 70/095

(57) ABSTRACT

A hybrid laser processing method and system for forming through-glass vias in glass substrates used in semiconductor packaging. The method includes drilling preliminary inner holes using an ultrafast laser, modifying surrounding molecular density with a homogenized infrared laser, and symmetrically etching to form straight-walled, zero-taper vias. A combined beam delivery system enables simultaneous ultrafast and IR laser exposure, improving processing efficiency and stress control. The system incorporates optical alignment, beam homogenization, in-situ monitoring, and integrated etching. The invention enhances mechanical reliability, precision, and electrical performance in high-density packaging applications.

### TECHNICAL FIELD

The present invention relates generally to semiconductor device fabrication and advanced packaging technologies. More specifically, the invention pertains to a precision laser processing method for forming through glass vias (TGVs) in glass or other similar substrate materials having comparable mechanical rigidity, dielectric properties, thermal stability, and coefficient of thermal expansion characteristics. The method is particularly suited for high-density interconnect applications, such as artificial intelligence (AI) chip packaging, photonic-electronic integration, and advanced system-in-package (SiP) devices.

### BACKGROUND

Glass substrates are becoming increasingly important in advanced semiconductor packaging due to their exceptional electrical characteristics, customizable coefficient of thermal expansion (CTE), superior mechanical rigidity, and availability in large-area and thin panel formats. Additionally, the inherently smooth surface of glass substrates supports the fabrication of ultra-fine interconnect features, crucial for achieving high-density integration in semiconductor devices. Despite these substantial benefits, glass substrates face notable reliability and manufacturing challenges, particularly due to their susceptibility to cracking from defects induced during dicing operations, and the frequent debonding of copper redistribution layers (RDL) resulting from inadequate adhesion on smooth glass surfaces. These issues significantly reduce substrate reliability, especially under repeated thermal cycling and mechanical stresses typical in semiconductor device operation.

Conventional fabrication processes for TGVs commonly rely on infrared (IR) lasers employing Gaussian intensity beam profiles. However, such Gaussian laser processing inherently produces uneven energy distributions within the substrate, resulting in non-uniform thermal expansion, significant residual stress accumulation, and uncontrolled initiation of micro-cracks. Notably, even lasers using homogeneous or “top-hat” beam profiles, while improving uniformity somewhat, still result in considerable residual stresses and micro-crack formation due to volumetric expansion and inherent energy absorption characteristics of the glass. Consequently, these conventional laser approaches, regardless of beam profiles, compromise via integrity, negatively affect electrical performance, and undermine the mechanical reliability of the substrate. Traditional methods thus fail to adequately address the stringent industry requirements for precise, small-scale, reliable via structures required in advanced semiconductor packaging.

To effectively address these long-standing challenges, the present invention introduces a hybrid laser exposure method designed specifically to control stress distribution and molecular density in glass substrates. The inventive method consists of three sequential steps, beginning with the creation of preliminary inner holes using an ultrafast laser, such as a femtosecond Deep Ultraviolet (DUV) laser, featuring a focused beam diameter typically around 5 μm. These inner holes serve as controlled expansion zones, accommodating volumetric changes occurring during subsequent laser irradiation and etching processes. This controlled expansion substantially reduces internal stress accumulation and mitigates the initiation and propagation of micro-cracks. While femtosecond DUV lasers are advantageous for their minimal thermal diffusion, high precision, and clean ablation characteristics, the inventive method is not limited to this laser type; other ultrafast lasers, such as picosecond lasers with comparable beam characteristics, pulse durations, and focused beam properties, may also be effectively employed.

Additionally, the invention supports multiple configurations and alternative geometric arrangements of these preliminary inner holes, enhancing the flexibility and design adaptability of the substrate. Multiple holes can be arranged in symmetrical patterns—such as circular, polygonal, or grid formations—to uniformly distribute internal stresses and facilitate uniform etching. Alternative geometric shapes, including elliptical, rectangular, square, hexagonal, or elongated slots, may also be adopted to optimize stress distribution and structural integrity based on specific electrical, thermal, and mechanical requirements.

Following the inner hole formation, the second step employs a modulated and homogenized IR laser beam to irradiate regions surrounding these holes. In contrast to conventional Gaussian or simple homogeneous beam lasers, the inventive method precisely modifies the molecular density of the glass uniformly, systematically reducing it from its initial density (m) to a modified, lower density state (m′). This carefully controlled molecular modification explicitly directs residual stress propagation outward (from m to m₁), preventing stress concentration and substantially reducing the likelihood of micro-crack initiation and substrate deformation. The method thereby achieves a predictable and stable internal stress profile, significantly enhancing mechanical reliability.

In the third step, symmetrical wet chemical etching is conducted through the previously drilled inner holes. The etching uniformly and symmetrically removes the laser-modified regions, producing straight, vertically oriented through-glass vias without undesirable tapering. The uniformity of the etching process ensures superior via geometry, robust mechanical stability, significantly reduced electrical resistance, and enhanced signal integrity essential for advanced semiconductor devices and high-frequency electronic applications.

Overall, the inventive hybrid laser exposure method offers substantial advantages over traditional fabrication techniques. By precisely managing molecular density modification and residual stress propagation, the method effectively minimizes micro-crack initiation and propagation, significantly improving mechanical reliability. Furthermore, it provides extensive design flexibility through various configurations and geometries of preliminary inner holes, enabling tailored optimization based on mechanical, electrical, or thermal design criteria. The precise formation of straight, zero-taper vias reduces electrical resistance, essential for efficient signal transmission in high-performance semiconductor applications, including artificial intelligence (AI) chip packaging and photonic-electronic integration. Additionally, the controlled stress management enables compatibility with thinner substrates without compromising mechanical integrity, aligning with industry trends toward compact, high-density electronic packages.

### SUMMARY OF THE INVENTION

The present invention relates to a hybrid laser processing method and system for forming through-glass vias (TGVs) in glass substrates, particularly suited for high-density semiconductor packaging applications. The invention addresses limitations of conventional laser drilling methods by combining the precision of ultrafast laser ablation with the uniform molecular modification capabilities of a homogenized IR laser. The invention enables the formation of high-aspect-ratio, straight-walled vias with substantially zero taper and minimal residual stress, thereby improving reliability, electrical performance, and scalability of glass-BASED interposers and substrates.

According to one aspect of the invention, the method includes: (1) forming at least one preliminary inner hole in the glass substrate using an ultrafast laser; (2) irradiating a region surrounding the preliminary hole with a homogenized IR laser to uniformly modify the molecular density and direct stress propagation; and (3) symmetrically etching the irradiated region to form a precision via structure. The method supports multiple hole configurations, including symmetrical, grid, or polygonal layouts, and accommodates varied hole geometries such as elliptical, rectangular, or elongated shapes.

In one embodiment, the ultrafast and IR lasers are delivered simultaneously to the substrate using a combined beam delivery system with co-axial alignment. This integrated configuration enables synchronized laser exposure, improves process efficiency, and enhances structural reliability by coupling ablation and molecular modification in real time. Alternatively, separate beam delivery systems may be used to allow sequential or spatially optimized processing.

The invention further provides a hybrid laser exposure system comprising an ultrafast laser source, a homogenized IR laser source, and a beam delivery system capable of simultaneous or sequential laser delivery. The system may include additional components such as beam homogenizers, beam combiners, substrate positioning stages, programmable controllers, real-time optical monitoring, and adaptive optics for active beam correction. An integrated wet etching station and automated process control software further support high-throughput, precision via formation.

The system architecture is also capable of recording and managing process data, supporting traceability and closed-loop manufacturing. The combined method and system offer a highly scalable, low-defect solution for panel-level packaging and advanced interconnect applications, such as AI chip packages, high-bandwidth memory, and heterogeneous integration platforms. The invention significantly improves via quality, eliminates substrate deformation, and enables thinner, higher-density glass core substrates by effectively managing residual stress and crack propagation throughout the TGV fabrication process.

### BRIEF DESCRIPTION OF THE DRAWINGS

FIGS. 1A to 1B are (A) is a schematic diagram illustrating a conventional semiconductor package structure including a glass interposer and a glass core substrate, (B) is a schematic diagram illustrating an advanced semiconductor package utilizing a single integrated glass core IC substrate in place of a separate interposer.

FIGS. 2A to 2D are (A) is a diagram showing the intensity distribution of a conventional infrared (IR) laser with a Gaussian beam profile used for TGV formation, (B) is a cross-sectional schematic illustrating stress propagation and micro-crack formation in a glass substrate during IR laser exposure using the Gaussian beam shown in (A), (C) is a cross-sectional schematic illustrating residual stress and tapered via formation remaining in the glass substrate after wet etching of laser-modified regions, (D) is a schematic diagram illustrating deformation and warpage of the glass substrate due to accumulated stress and the SEWARE effect following conventional laser processing.

FIGS. 3A to 3F are (A) is a cross-sectional diagram illustrating the first step of the inventive hybrid laser method, where a preliminary inner hole is formed by an ultrafast laser, (B) is a diagram showing the second step of the hybrid method, wherein a homogenized IR laser beam is used to modify the molecular density of the glass surrounding the desired via region, (C) is a schematic showing the third step, in which symmetrical wet etching forms a straight-walled via, (D) a schematic view illustrating an alternative embodiment with multiple preliminary inner holes arranged in a symmetrical pattern, (E) is a schematic view showing an alternative embodiment in which the inner holes are arranged in a regular grid pattern, (F) illustrates various geometric configurations of preliminary inner holes, including elliptical, rectangular, polygonal, and slot-type geometries.

FIGS. 4A to 4B are (A) is a cross-sectional view of a TGV formed using a conventional IR laser process, showing defects such as taper, residual stress, and micro-cracks, (B) is a cross-sectional view of a TGV formed using the inventive hybrid laser process, showing a straight-walled via with minimal defects and uniform structure.

FIG. 5 is a conceptual molecular diagram illustrating uniform molecular density reduction and outward stress propagation achieved by homogenized IR laser exposure.

FIGS. 6A to 6F are (A) is a schematic diagram of a basic beam delivery system (BDS) for a DUV laser including an attenuator and focusing lens, (B) is a schematic diagram of an enhanced DUV laser BDS configuration incorporating a galvanometer scanner for beam positioning, (C) is a schematic of a DUV laser BDS configuration including a beam expanding telescope (BET) for beam diameter control, (D) is a schematic showing a combined DUV laser BDS configuration with both a BET and galvanometer scanner, (E) is a diagram showing a DUV laser BDS further enhanced by inclusion of a quarter wave plate (QWP) for polarization control, (F) is a comprehensive BDS configuration for a DUV laser integrating attenuator, BET, galvanometer scanner, and QWP for full beam control and optimization.

FIGS. 7A to 7C are (A) is a schematic diagram of a basic IR laser BDS configuration including an attenuator, BET, and image lens, (B) is a schematic diagram of an IR laser BDS enhanced with a homogenizer and condensing lens for uniform beam intensity distribution, (C) illustrates an advanced IR laser BDS configuration further enhanced with a field lens for efficient beam direction and uniform energy delivery.

FIGS. 8A to 8B are (A) is a schematic diagram of an optical attenuator configuration using a linear polarizer and half-wave plate (HWP), applicable to both IR and DUV laser systems, (B) is a diagram illustrating a homogenizer configuration using fly-eye or cylindrical lens arrays to achieve a top-hat intensity profile at the substrate surface.

FIG. 9 is a detailed schematic of a combined DUV and IR hybrid laser exposure system showing coaxial beam delivery and major optical components including attenuators, BETs, scanners, homogenizers, photomask, and imaging optics.

FIG. 10 is a control block diagram illustrating the integration and coordination of all subsystems in the hybrid laser processing system, including the main control PC, beam delivery systems, motion stages, inspection tools, and energy monitoring equipment.

### DETAILED DESCRIPTION

The following detailed description is provided to enable any person skilled in the art to make and use the invention and is presented in the context of particular embodiments and implementations. It is to be understood that the invention is not limited to the specific embodiments disclosed, but rather includes all modifications, equivalents, and alternatives falling within the spirit and scope of the appended claims. Features illustrated or described in connection with one embodiment may be combined with the features of other embodiments, even if not explicitly stated, to yield further embodiments. The invention is described herein with reference to illustrative examples and accompanying figures, which serve to explain various aspects of the invention in a clear and enabling manner. These embodiments are provided for illustrative purposes and do not limit the scope of the invention. It should be appreciated that certain features shown in the drawings may be omitted or modified in alternative embodiments, and that the same or equivalent functionality may be implemented in different ways.

The embodiments described address significant challenges in the semiconductor packaging industry, particularly those associated with glass substrate processing and through-glass via (TGV) formation. The invention is especially relevant to high-density, high-reliability applications, including—but not limited to—advanced electronic devices such as artificial intelligence (AI) chip packaging, high-bandwidth memory modules, and logic device integration platforms. All directional and dimensional terminology is used for convenience and should not be construed as limiting. Unless otherwise stated, materials, dimensions, process parameters, and configurations may vary within the scope of the invention.

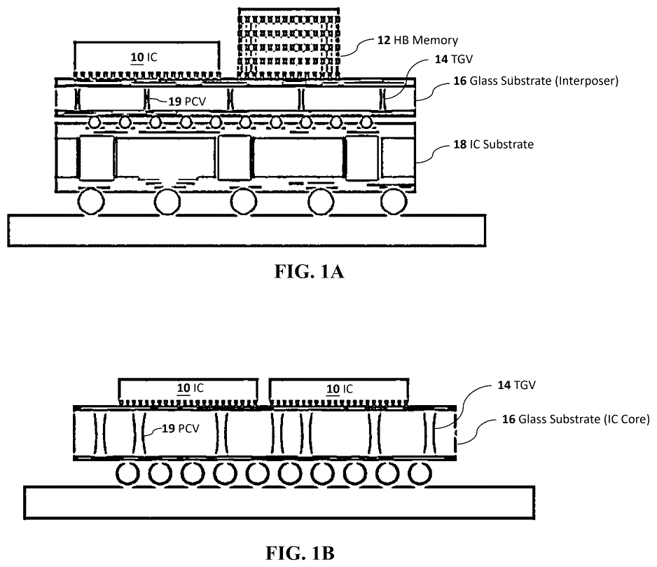

FIG. 1A illustrates a conventional packaging architecture employing both a glass interposer 16 and an IC substrate 18. In this configuration, the glass interposer 16 is positioned between high-bandwidth (HB) memory 12 and integrated circuits (ICs) 10 and the underlying IC substrate 18. The glass interposer typically has a coefficient of thermal expansion (CTE) of approximately 3 ppm/°C and a thickness of around 400 μm. This architecture was originally developed to replace large-area, high-cost silicon interposers. It supports industry trends toward thinner, smaller-diameter packaging while offering cost-effective and thermally stable performance. However, this configuration still requires an additional substrate layer 18 beneath the interposer 16, adding process complexity. The use of glass in both the interposer 16 and the substrate 18 imposes stringent requirements on via density, process cleanliness, and reliability—particularly with the inclusion of through-glass vias (TGVs) 14 and plated copper vias (PCVs) 19. These demands are particularly critical in advanced packaging applications for high-performance computing and artificial intelligence (AI) devices, where signal integrity and thermal stability are essential.

FIG. 1B shows an advanced packaging configuration that uses a single, integrated glass core IC substrate 16, thereby eliminating the need for a separate interposer. This configuration combines interconnection and redistribution functions within a single, thicker glass layer, typically about 800 μm thick, and generally exhibits a higher CTE of approximately 7 ppm/°C. By removing the interposer, this structure simplifies the overall package stack and reduces vertical height. To achieve the same functionality as multi-layer systems, the glass core 16 must support higher via densities, incorporating both TGVs 14 and PCVs 19. This allows for direct die mounting of ICs 10 onto the glass core 16, resulting in improved signal performance, greater mechanical reliability, and enhanced thermal uniformity. The compact structure is particularly suited for panel-level manufacturing processes designed for large-area, high-throughput production of AI processors, memory packages, and heterogeneous logic devices. However, the implementation of high-density, fine-pitch, and high-aspect-ratio vias in thicker glass substrates introduces technical challenges in laser processing and etching, challenges directly addressed by the hybrid laser method disclosed in this invention.

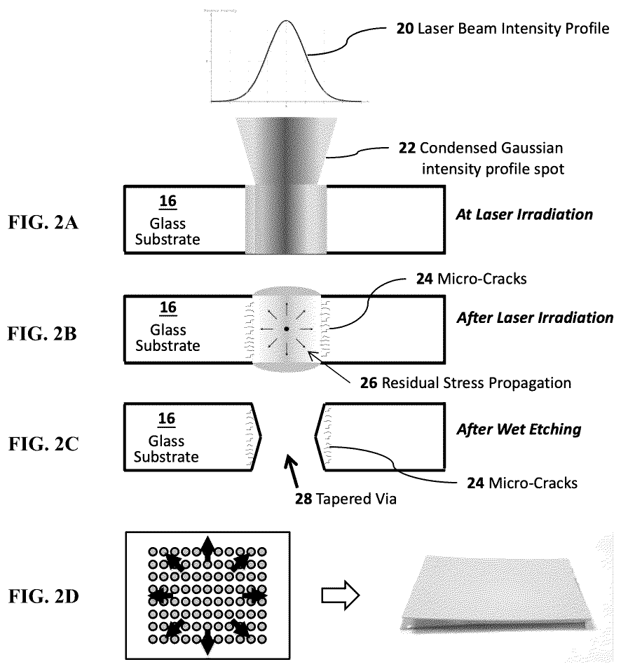

FIG. 2 illustrates key limitations and structural consequences associated with conventional Through-Glass Via (TGV) fabrication methods utilizing infrared (IR) lasers with Gaussian intensity profiles.

FIG. 2A shows a schematic view of the laser beam intensity profile 20 used in traditional IR-based TGV processing. The Gaussian profile 22 concentrates the energy at the center of the beam, resulting in a steep intensity gradient. This non-uniform distribution causes uneven thermal energy delivery across the irradiated region of the glass substrate 16, initiating volumetric expansion differentials within the substrate structure.

FIG. 2B depicts the glass substrate 16 during and immediately after laser irradiation. As energy absorption varies radially due to the Gaussian beam shape, localized heating and thermal gradients cause residual stress propagation 26 within and around the laser-affected zone. These thermal-induced stresses not only distort the internal structure but also trigger the formation of micro-cracks 24 extending radially or vertically through the glass substrate. These defects introduce localized weakness and reduce mechanical reliability.

FIG. 2C illustrates the condition of the glass substrate 16 after wet etching has been performed to remove the laser-modified regions. Although the modified material has been chemically removed, residual stress propagation 26 remains embedded within the surrounding glass, particularly around the sidewalls of the vias. The micro-cracks 24 remain partially exposed or embedded at the boundary regions, contributing to further mechanical degradation over time. This non-uniform distribution causes uneven thermal energy delivery across the irradiated region of the glass substrate 16, initiating volumetric expansion differentials within the substrate structure.

As a result, the via profile becomes tapered, forming non-vertical sidewalls identified as tapered via 28. This tapering arises from two primary causes. First, the molecular density at the center of the IR laser spot is reduced more significantly than at the edges, making the central region more susceptible to removal by the etching solution. Second, during the etching process, the exposed regions on the top and bottom surfaces of the glass substrate are attacked first, leading to faster removal from those surfaces and forming a sloped profile that extends inward from the top and bottom. These tapered geometries can negatively impact electrical performance and mechanical reliability, making them unsuitable for high-density, fine-pitch interconnect applications.

FIG. 2D demonstrates the resulting deformation of the substrate following the combined effects of non-uniform irradiation, residual stress, and micro-crack propagation. This is commonly referred to as the “SEWARE” effect—substrate expansion warpage after residual energy—wherein the glass substrate exhibits visible out-of-plane distortion and twisting. This warpage severely compromises substrate planarity and flatness, negatively impacting alignment accuracy, lamination quality, and downstream assembly in advanced packaging lines. Such deformation is particularly problematic in panel-level packaging or large-area substrates used in artificial intelligence (AI) processors, high-bandwidth memory, and advanced logic devices, where micron-level tolerances are required.

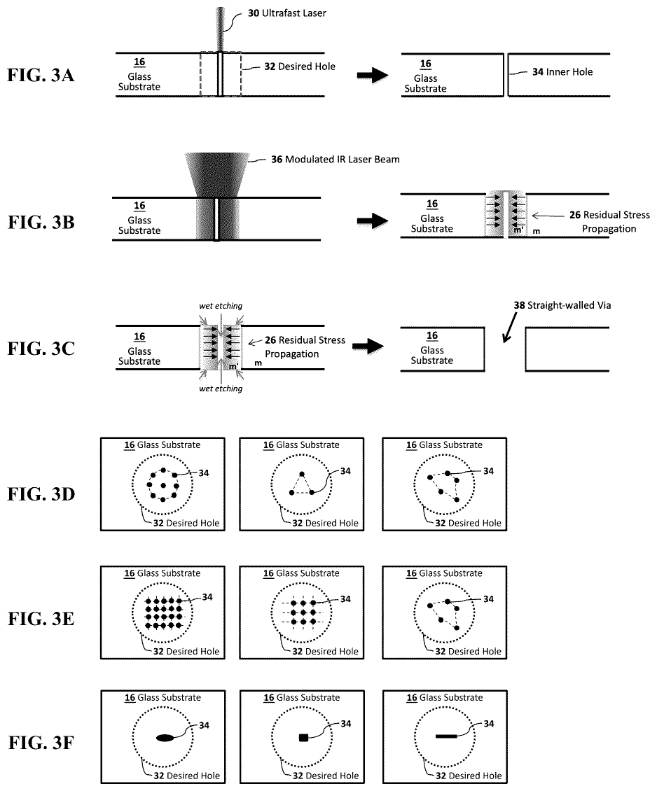

The inventive hybrid laser exposure method described in FIG. 3 directly addresses these issues. By introducing a preliminary inner hole formation step using ultrafast lasers followed by homogenized infrared molecular modification, the present invention minimizes residual stress concentration, prevents micro-crack propagation, and achieves dimensional stability post-etch. As a result, it enables reliable formation of high-aspect-ratio, zero-taper vias while maintaining substrate integrity and flatness critical for next-generation semiconductor integration.

FIG. 3 illustrates a comprehensive sequence and various embodiments of the inventive hybrid laser method for forming precision Through-Glass Vias (TGVs).

In the first step, depicted in FIG. 3A, a preliminary inner hole 34 is precisely drilled within the glass substrate 16 using an ultrafast laser 30, such as a femtosecond Deep Ultraviolet (DUV) laser or other ultrafast laser having similar ultrashort pulse characteristics and minimal thermal diffusion. The ultrafast laser 30 directs a focused beam at a target location indicated by the desired hole 32, forming the inner hole 34. This inner hole 34 acts as a controlled expansion zone, effectively accommodating volumetric changes that occur during subsequent laser processing. The desired hole 32 in this figure is not yet formed, but rather designates the region that will be later modified by IR laser exposure.

The inner hole 34 serves two primary functions. First, it provides a localized volume for expansion that reduces the likelihood of crack formation due to the volumetric change induced by later IR laser processing. Second, it allows etchant fluid to penetrate and initiate etching from multiple directions, including the top surface, bottom surface, and sidewalls, which facilitates uniform material removal and suppresses taper formation in the final via structure.

By introducing these carefully positioned expansion zones in advance of the main via structure, residual stress accumulation and micro-crack formation within the glass substrate 16 are significantly mitigated, thereby enhancing overall substrate integrity and long-term reliability.

The inventive method further provides substantial flexibility regarding the arrangement and geometry of these preliminary inner holes 34. FIG. 3D depicts an alternative embodiment in which multiple inner holes 34 are symmetrically arranged in circular, polygonal, or other regular patterns, optimizing uniform stress distribution. Similarly, as illustrated in FIG. 3E, another alternative configuration comprises multiple inner holes 34 arranged in a regular grid pattern. This grid arrangement ensures uniform molecular density modification and controlled stress distribution across large substrate areas, beneficial for maintaining structural integrity and reducing localized stress concentrations. Moreover, as shown in FIG. 3F, preliminary inner holes 34 may adopt various geometric shapes, including elliptical, rectangular, polygonal, or elongated slot-like geometries. Such geometric flexibility allows tailored optimization for specific mechanical, electrical, and thermal performance requirements relevant to diverse electronic device applications. It should be understood that the invention encompasses any and all geometric configurations or combinations thereof for the preliminary inner holes 34, ensuring maximum adaptability and versatility for a broad range of applications and design considerations.

In the second step, illustrated by FIG. 3B, a homogenized and modulated infrared laser beam 36 is used to irradiate regions of the glass substrate 16 surrounding the inner hole 34. The beam 36 is applied at the site of the desired hole 32 and is configured to uniformly reduce the molecular density of the irradiated zone from an initial value (m) to a modified value (m′). The homogenized IR beam 36 produces a consistent top-hat intensity profile, which induces uniform outward residual stress propagation (m to m′) without generating concentrated thermal gradients. This uniform molecular density modification reduces internal stress accumulation, prevents micro-crack initiation, and enhances the structural integrity of the glass surrounding the via.

The third and final step, depicted in FIG. 3C, involves symmetrical wet chemical etching through the substrate 16. Thanks to the uniform molecular modification achieved during the IR laser exposure, the etching process proceeds evenly and selectively in the regions surrounding the desired hole 32. The result is the straight-walled via 38 with straight, vertically oriented sidewalls and minimal or no taper. This geometry ensures excellent via performance, including high electrical conductivity, low resistance, and enhanced mechanical durability—key features for next-generation electronic packaging.

Overall, the hybrid laser exposure method described in FIG. 3 effectively overcomes limitations of conventional laser drilling techniques. By combining ultrafast preliminary hole formation, stress-controlled molecular density modification, and precision chemical etching, this method supports high-reliability, high-density TGV structures essential for advanced semiconductor applications, including artificial intelligence (AI) chip packaging, memory integration, and logic device interconnection.

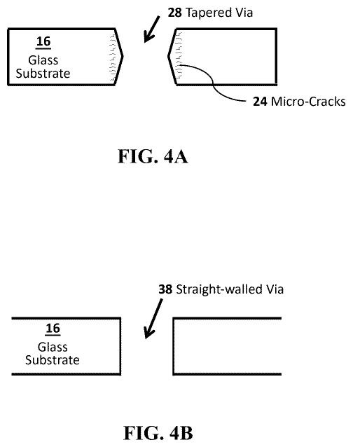

FIG. 4 provides a comparative visualization that highlights the performance differences between conventional TGV fabrication methods and the inventive hybrid laser method.

FIG. 4A illustrates a cross-sectional view of a glass substrate 16 processed using conventional IR laser techniques with Gaussian intensity profiles. The via 28 produced by this method exhibits a tapered geometry, indicating non-uniform material removal and uncontrolled energy distribution during laser exposure and etching. The surrounding substrate contains visible residual stress zones and multiple micro-cracks 24, which propagate from the via sidewalls into the adjacent glass structure. These defects are symptomatic of uneven thermal expansion and uncontrolled stress gradients, which ultimately lead to mechanical instability and substrate warpage. Such tapered vias and stress-induced damage reduce structural reliability and can impair electrical continuity and packaging integrity in high-density applications.

FIG. 4B, in contrast, demonstrates the results achieved using the inventive hybrid laser exposure method. The glass substrate 16 features a straight-walled via 38, which exhibits uniform vertical sidewalls and precise geometry with no taper. This improved via profile results from the three-step process involving ultrafast inner hole drilling, homogenized IR laser molecular modification, and symmetrical chemical etching. The absence of micro-cracks or stress-related deformation confirms the stress-balancing effect of the inner hole 34 and the uniform energy distribution achieved by the homogenized IR beam. As a result, the via structure exhibits enhanced mechanical reliability, superior electrical performance, and high reproducibility—making it ideally suited for next-generation electronic packaging, including AI processors and high-bandwidth interconnects.

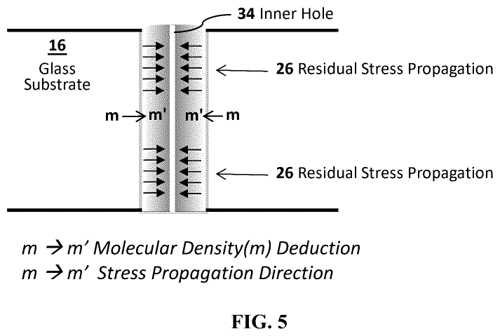

FIG. 5 provides a detailed molecular-level depiction of the stress and density modification that occurs during the second step of the inventive hybrid laser process, specifically during infrared (IR) laser irradiation.

The diagram shows a cross-sectional view of the glass substrate 16 with a centrally located preliminary inner hole 34. During IR laser irradiation, the region of the glass surrounding the inner hole 34 undergoes a uniform and controlled molecular density reduction, transitioning from an initial state (m) to a lower-density modified state (m′). This transformation is initiated by the homogenized IR laser beam and occurs symmetrically around the inner hole.

Importantly, FIG. 5 also illustrates the direction of residual stress propagation 26 induced by the molecular modification. As shown by the directional arrows, the residual stress propagates outwardly from the region of reduced molecular density (m′) into the surrounding, unmodified regions (m) of the glass substrate. This outward propagation of stress ensures that the stress field is redistributed away from the critical via formation zone, thereby minimizing localized stress concentrations that would otherwise lead to deformation or crack formation.

By precisely managing both the molecular density and residual stress propagation 26, the method stabilizes the internal structure of the substrate and enables the formation of clean, straight-walled vias with minimal mechanical distortion. The balance of stress across the modified and unmodified regions is essential to achieving high structural integrity, substrate flatness, and long-term reliability in high-density semiconductor packaging applications.

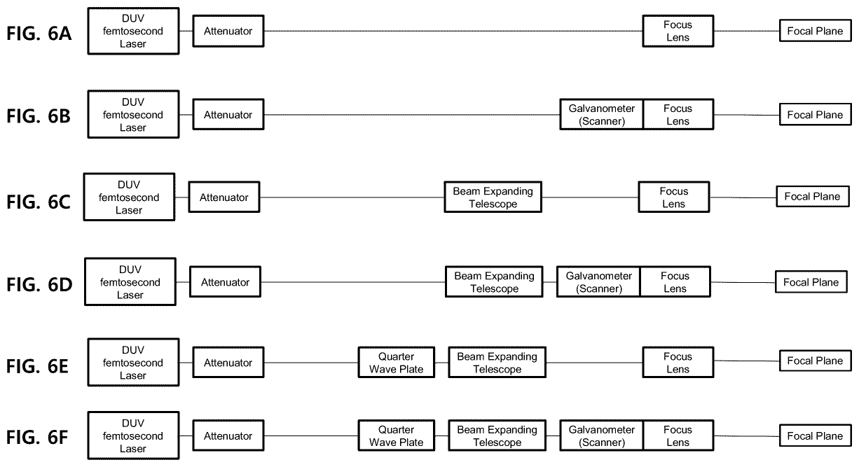

FIG. 6 illustrates various exemplary optical configurations of the Beam Delivery System (BDS) employing a Deep Ultraviolet (DUV) femtosecond laser, particularly suited for precision laser drilling processes used in through-glass via (TGV) formation. Each configuration, FIG. 6A through FIG. 6F, offers distinct functional advantages, enabling flexibility and customization based on specific application requirements.

FIG. 6A illustrates a fundamental optical configuration. In this basic setup, the DUV femtosecond laser beam passes first through an attenuator, which precisely adjusts the energy of the laser beam, thereby controlling the energy density at the focal plane. A focusing lens positioned downstream from the attenuator then concentrates the adjusted laser beam onto the substrate surface. This simplified arrangement provides direct energy modulation and precise beam focusing, suitable for fundamental drilling applications requiring minimal optical complexity.

FIG. 6B depicts an enhanced optical configuration integrating a galvanometer scanner downstream from the attenuator. The scanner rapidly adjusts the lateral position of the focused laser beam across the substrate surface without physically moving the substrate or other optical components. This significantly improves processing speed and positional accuracy, allowing rapid and precise drilling of multiple holes in complex or densely patterned arrays, which is ideal for advanced packaging applications requiring high positional repeatability and throughput.

Typically, the galvanometer offers faster positioning speed compared to an X-Y stage. In conventional implementations, laser processing within the Field of View (FOV) of the galvanometer is performed first, after which the X-Y stage steps to a new region for the next round of processing. This is known as the “step-and-repeat” method. Although not shown in the drawing, to maximize processing speed, the galvanometer may also be synchronized with the motion of the X-Y stage. In such a configuration, the galvanometer dynamically tracks the moving X-Y stage and continuously adjusts the beam position in real time. This enables the effective extension of the galvanometer's processing field (FOV) to cover the entire substrate area handled by the X-Y stage.

FIG. 6C presents a configuration incorporating a Beam Expanding Telescope (BET) located after the attenuator and before the focusing lens. The BET precisely controls the laser beam diameter and divergence angle, adjusting the spot size and energy density at the focal plane. This setup allows fine-tuning of hole diameters and drilling depth profiles, essential in applications demanding precise dimensional control over via geometry, aspect ratio, and sidewall smoothness.

FIG. 6D illustrates an integrated optical setup combining both the Beam Expanding Telescope (BET) and galvanometer scanner functionalities. This advanced integration provides simultaneous precision control over beam diameter, divergence, and rapid positional adjustment of the laser spot. Such comprehensive capability is particularly advantageous for intricate drilling applications requiring exact beam characteristics and dynamic beam positioning, enabling highly versatile and high-quality micro-machining across diverse and complex substrate configurations.

FIG. 6E illustrates an optical configuration further enhanced by incorporating a Quarter Wave Plate (QWP) downstream from the Beam Expanding Telescope (BET) and upstream from the focusing lens. The QWP converts the incoming linearly polarized laser beam into circular polarization, ensuring consistent energy absorption and uniform material removal regardless of processing direction. This arrangement effectively eliminates polarization-dependent variations in hole quality, ensuring highly uniform and repeatable via results, especially beneficial in precision-critical semiconductor applications.

FIG. 6F represents a comprehensive optical configuration integrating all previously described elements: attenuator, Beam Expanding Telescope (BET), galvanometer scanner, and Quarter Wave Plate (QWP). This highly integrated beam delivery system maximizes operational flexibility, drilling precision, and overall process reliability. It simultaneously provides precise beam diameter and divergence control, rapid and accurate laser spot positioning, finely controlled energy density modulation, and uniform polarization management. This complete configuration supports sophisticated TGV formation requirements, fulfilling stringent manufacturing standards for via uniformity, reproducibility, throughput, and dimensional precision in semiconductor and advanced electronic packaging applications. and advanced electronic packaging applications.

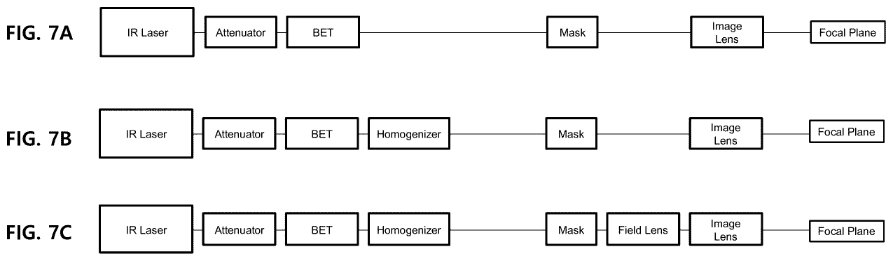

FIG. 7 illustrates exemplary optical configurations of an IR laser-based BDS utilized in the inventive hybrid laser exposure method, specifically optimized for precise molecular density modifications in glass substrates during TGV fabrication.

FIG. 7A depicts a basic optical layout. In this fundamental arrangement, the IR laser beam initially passes through an attenuator, which precisely adjusts the beam′s energy, ensuring appropriate energy density for forming clear images on the glass surface. Subsequently, the Beam Expanding Telescope (BET) enlarges the laser beam to sufficiently cover patterns defined within a mask. The size of these mask patterns directly determines the size of the resulting image on the glass substrate. Finally, an image lens accurately projects these defined mask patterns onto the focal plane at the glass surface, enabling controlled and precise molecular modification.

FIG. 7B illustrates an enhanced optical configuration incorporating a homogenizer, typically consisting of a fly-eye lens array or a cylindrical lens array, together with a condensing lens. The homogenizer divides the beam into multiple beamlets and then recombines these beamlets, ensuring their uniform overlap onto the mask pattern. BET precisely adjusts the laser beam size to match the effective aperture of the homogenizer. This setup significantly improves the uniformity of the intensity distribution across the mask surface, achieving a highly consistent molecular modification profile, essential for high-precision and high-reliability TGV fabrication.

FIG. 7C presents an advanced optical configuration further enhanced by the addition of a field lens into the arrangement shown in FIG. 7B. The field lens efficiently directs the laser beam passing through the mask toward the imaging lens. This redirection maximizes the Beam Utilizing Factor (BUF), significantly enhancing beam efficiency and intensity consistency at the imaging lens. As a result, this configuration delivers an exceptionally uniform and accurately defined intensity profile at the focal plane, ensuring precise, uniform molecular density modifications necessary for consistent, defect-free through-glass via structures.

These varied configurations depicted in FIG. 7 provide adaptable and precise optical solutions, effectively meeting the stringent requirements for reliable and uniform molecular modification in advanced semiconductor packaging applications.

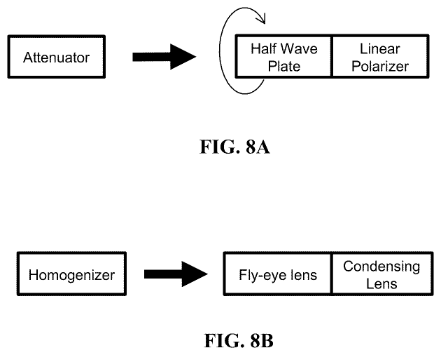

FIG. 8 illustrates exemplary implementations of optical attenuation systems employed in the Beam Delivery System (BDS) of the inventive hybrid laser exposure system. Specifically, FIG. 8 shows configurations employing a combination of a Linear Polarizer and a Half-Wave Plate (HWP) for precise laser energy control. The configurations depicted in FIG. 8A and FIG. 8B can be interchangeably utilized for both infrared (IR) and deep ultraviolet (DUV) femtosecond laser beam delivery systems (BDS), providing versatile energy modulation across different laser processing steps.

FIG. 8A depicts a fundamental optical attenuation configuration where laser beam transmittance is precisely controlled by varying the rotational orientation angle of the Half-Wave Plate (HWP) relative to a fixed linear polarizer. This straightforward arrangement allows exact and continuous modulation of laser beam intensity, facilitating precise energy density management at the substrate focal plane. Such controlled energy modulation ensures reproducible and uniform laser-material interactions, resulting in consistent via quality, accurate hole geometries, and minimized process variability across large-area glass substrates.

Additionally, the configuration shown in FIG. 8A can also be adapted to IR laser systems utilized for molecular density modification. When employed with IR lasers, a beam homogenizer, such as a fly-eye or cylindrical lens array, is introduced into the beam delivery system. This homogenizer produces a highly uniform, “top-hat” intensity profile on the substrate surface, significantly improving the quality and consistency of molecular density modification by minimizing thermal gradients and stress concentration effects, thus optimizing the subsequent chemical etching precision and via reliability.

FIG. 8B illustrates an enhanced optical configuration of the homogenizer component used in conjunction with optical attenuation. Specifically, the homogenizer shown in FIG. 8B consists of a fly-eye lens or cylindrical lens array that segments the incoming laser beam into a two-dimensional array of smaller beamlets. A condensing lens is positioned downstream to recombine these beamlets, overlapping them onto a defined focal area. This overlapping effect transforms the originally Gaussian-distributed laser beam intensity into a highly uniform intensity profile at the substrate surface, ensuring consistent energy deposition and uniform molecular density modification across the entire irradiated area. This configuration dramatically reduces intensity variations, promoting uniform via quality, improving substrate reliability, and significantly enhancing the overall reproducibility and precision of the hybrid laser process.

These optical attenuation and homogenization configurations (FIG. 8A and FIG. 8B) integrated within the inventive hybrid laser exposure system ensure precise, consistent, and highly controlled laser processing conditions, essential for reliably producing uniform, high-aspect-ratio, and stress-controlled through-glass vias suitable for advanced semiconductor packaging applications.

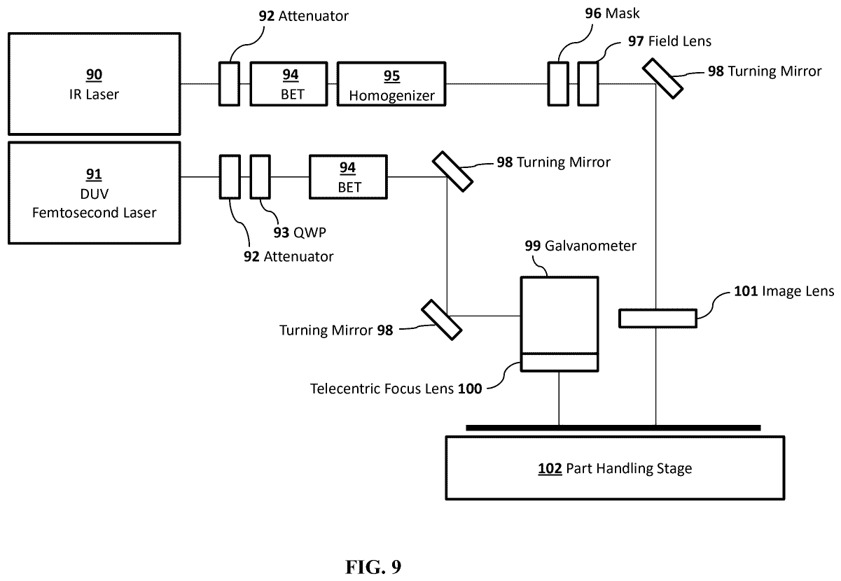

FIG. 9 illustrates an enhanced and integrated embodiment of the inventive hybrid laser exposure system, configured for simultaneous delivery of ultrafast Deep Ultraviolet (DUV) femtosecond laser radiation from a DUV laser 91 and homogenized Infrared (IR) laser radiation from an IR laser 90 to a glass substrate. This advanced beam delivery configuration enables concurrent, precision execution of two critical laser processes: (1) preliminary inner hole drilling using the ultrafast DUV laser 91, and (2) precise molecular density modification around the drilled holes using the homogenized IR laser 90. Integration of these beams into a common optical platform eliminates alignment mismatches between discrete laser systems, increases throughput, and enhances via formation uniformity.

The DUV femtosecond laser beam path begins at the DUV laser 91. The output beam passes through a laser attenuator 92, which adjusts the energy level as needed for precision drilling. Downstream from the attenuator 92, a quarter wave plate (QWP) 93 modifies the polarization state of the beam from linear to circular, reducing directional variability and improving via symmetry. The beam then enters a beam expanding telescope (BET) 94, which controls the beam′s diameter and divergence. After exiting the BET 94, the beam is redirected via turning mirror 98 to a galvanometer scanner 99, which dynamically positions the beam across the substrate without the need for stage movement. A telecentric focus lens 100 downstream from the galvanometer 99 ensures uniform spot size and focal quality over the scan field, facilitating the formation of high-aspect-ratio, straight-walled vias.

Simultaneously, the IR laser beam path begins at the IR laser 90. The beam passes through a second laser attenuator 92, enabling precise modulation of IR energy. The beam is then expanded using another beam expanding telescope (BET) 94 and passed through a beam homogenizer 95, which converts the Gaussian energy distribution into a spatially uniform top-hat profile for consistent modification. This homogenized beam proceeds through a photomask 96, which defines the spatial exposure pattern, and then passes through a field lens 97 to improve beam transmission efficiency. A turning mirror 98 directs the patterned beam into an image lens 101, which focuses the pattern onto the target surface.

Both DUV and IR beams converge coaxially through the optical elements and are delivered to a common region on the glass substrate positioned on a part handling stage 102. The part handling stage 102 includes motorized XYZ motion to support programmable, high-precision via layout patterning across large substrates.

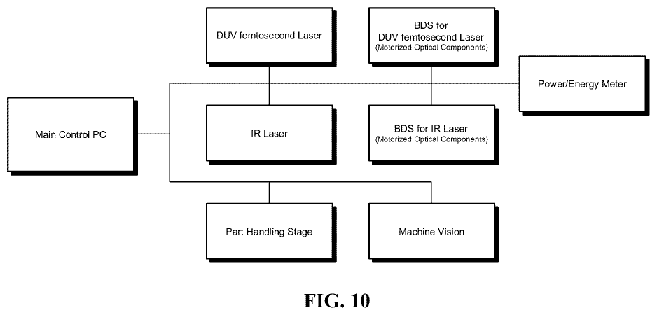

This integrated hybrid system further includes real-time process feedback and monitoring (not shown) to measure and control beam intensity, alignment, and pulse timing. All operations, including laser firing, beam steering, and stage control, are coordinated by a programmable control system (shown in FIG. 10), ensuring accurate temporal and spatial synchronization of the ultrafast and IR laser processes. This configuration minimizes residual thermal stress, eliminates post-etch deformation, and ensures high-yield, high-reliability via structures, ideally suited for advanced semiconductor packaging including AI processors, high-bandwidth memory modules, and next-generation interconnect architectures.

FIG. 10 illustrates the control architecture of the integrated hybrid laser exposure system detailed in FIG. 9, highlighting the system-level interconnections and comprehensive control components required to execute synchronized and precise Through-Glass Via (TGV) fabrication processes.

The central component depicted in FIG. 10 is the Main Control PC, serving as the primary controller orchestrating all subsystem operations. This programmable control system precisely synchronizes, monitors, and adjusts all laser processing operations, including laser beam generation, optical component positioning, energy management, substrate handling, and real-time inspection feedback.

Connected to the Main Control PC is the Beam Delivery System (BDS) for the DUV femtosecond laser, which includes motorized optical components for automated and precision-controlled beam adjustments. This subsystem, as described in FIG. 9, incorporates key optical elements such as a Laser Attenuator for precise energy modulation, a Quarter Wave Plate (QWP) to maintain circular beam polarization, and a Beam Expanding Telescope (BET) for accurate control of beam divergence and spot size. Additional motorized optical components within the DUV laser path include Turning Mirrors, a Galvanometer Scanner for rapid beam positioning, and a Telecentric Focusing Lens ensuring consistent beam size and uniformity across the processing field.

Similarly, the Main Control PC also interfaces with the IR laser Beam Delivery System (BDS), which likewise employs motorized optical components for exact beam positioning and intensity control. As previously described in FIG. 9, this subsystem includes critical optical elements such as a dedicated Laser Attenuator for controlled IR energy delivery, a Beam Expanding Telescope (BET) for precise beam size management, and a Beam Homogenizer designed to produce a uniform “top-hat” intensity distribution. Additionally, this IR laser path incorporates a Mask for precisely defining irradiation patterns, a Field Lens for maximizing beam efficiency, Turning Mirrors for accurate beam alignment, and an Image Lens that accurately projects mask patterns onto the glass substrate surface.

FIG. 10 further illustrates the Part Handling Stage connected to the Main Control PC, comprising motorized positioning elements (XYZ stages) responsible for precisely aligning and translating the glass substrate in coordination with laser beam positioning systems. Accurate, programmable substrate movements enable precise via placement patterns across large-area substrates and allow dynamic adjustments during laser processing.

To ensure optimal energy control and monitoring during laser exposure processes, FIG. 10 includes a Power/Energy Meter directly linked to the Main Control PC. This meter continuously measures laser output parameters, providing real-time feedback on beam power and pulse energy, allowing immediate adjustments and ensuring precise control of processing conditions throughout the fabrication cycle.

Additionally, FIG. 10 depicts a Machine Vision system connected to the Main Control PC, providing in-situ inspection and immediate optical feedback during substrate processing. This vision-based inspection continuously evaluates parameters such as via geometry, positional accuracy, and overall substrate quality, facilitating real-time adjustments and enhancing process reproducibility, consistency, and reliability.

Collectively, the interconnected components depicted in FIG. 10 form a tightly integrated control framework essential for high-precision TGV fabrication. The Main Control PC, by managing synchronized operations across the DUV femtosecond laser BDS, IR laser BDS, Part Handling Stage, Power/Energy Meter, and Machine Vision system, ensures precise temporal and spatial alignment between preliminary hole drilling and molecular density modification steps. This comprehensive control capability significantly reduces thermal stress, optimizes via geometry, and maximizes manufacturing reliability, supporting advanced, high-density semiconductor packaging applications, including artificial intelligence (AI) chips and other high-performance electronics.

What is claimed is:

1. A method of forming a through-glass via (TGV) in a glass substrate, comprising:
(a) forming at least one preliminary inner hole in the glass substrate using an ultrafast laser beam;
(b) irradiating a region surrounding the at least one preliminary inner hole with a homogenized infrared (IR) laser beam to modify molecular density of the glass and direct residual stress propagation; and
(c) etching the irradiated region to form a via having substantially vertical sidewalls and minimal taper.

2. The method of claim 1, wherein the ultrafast laser beam is produced by a femtosecond deep ultraviolet (DUV) laser.

3. The method of claim 1, wherein forming the at least one preliminary inner hole comprises forming a plurality of inner holes arranged in a geometric pattern selected from the group consisting of circular, grid, polygonal, and linear patterns.

4. The method of claim 1, wherein the preliminary inner hole comprises a shape selected from the group consisting of elliptical, rectangular, polygonal, and elongated slot geometries.

5. The method of claim 1, wherein the homogenized IR laser beam has a top-hat spatial intensity profile and reduces molecular density from an initial state to a modified state, thereby facilitating outward residual stress propagation.

6. The method of claim 1, wherein steps (a) and (b) are performed concurrently using a coaxial beam path.

7. The method of claim 1, wherein the etching in step (c) comprises symmetrical wet chemical etching of the laser-modified regions.

8. The method of claim 1, wherein the via formed exhibits reduced residual stress and mitigated formation of micro-cracks.

9. The method of claim 1, wherein the glass substrate comprises a glass core substrate configured for a semiconductor package selected from artificial intelligence (AI) chips, memory modules, or logic devices.

10. The method of claim 1, wherein the via has a height-to-width aspect ratio greater than 3:1.

11. A hybrid laser exposure system for forming a through-glass via (TGV) in a glass substrate, comprising:
an ultrafast laser source configured to form at least one preliminary inner hole in the glass substrate;
a homogenized infrared (IR) laser source configured to modify molecular density in a region surrounding the at least one preliminary inner hole; and
a beam delivery system configured to direct laser beams from both the ultrafast laser source and the IR laser source onto a common region of the glass substrate.

12. The system of claim 11, wherein the beam delivery system comprises a beam combiner configured to merge optical paths of the ultrafast laser source and the IR laser source into a coaxial beam path.

13. The system of claim 11, further comprising a beam homogenizer disposed in an optical path of the IR laser source, the beam homogenizer configured to generate a spatially uniform intensity distribution.

14. The system of claim 11, further comprising beam steering optics and a motorized substrate positioning stage configured to control spatial positioning of the laser beams and the glass substrate.

15. The system of claim 11, further comprising an optical monitoring and feedback system configured to measure beam characteristics selected from the group consisting of intensity, pulse duration, spot size, and beam alignment.

16. The system of claim 11, further comprising a programmable controller configured to synchronize laser pulse timing and substrate movement.

17. The system of claim 11, wherein the ultrafast laser source is a femtosecond laser configured to produce pulses of less than 500 femtoseconds, and the IR laser source is a fiber laser configured for modulated infrared pulse delivery.

18. The system of claim 11, further comprising a photomask and imaging optics for pattern projection in the IR laser path.

19. The system of claim 11, further comprising a wet chemical etching station positioned downstream of the laser exposure station.

20. The system of claim 19, wherein the wet chemical etching station comprises fluid control subsystems for regulating etchant delivery, temperature, and exposure duration.
